(19) United States
(12) Patent Application Publication
(10) Pub. No.: US 2025/0167134 A1
(43) Pub. Date: May 22, 2025

(54) SEMICONDUCTOR PACKAGE STRUCTURE AND METHOD OF MANUFACTURING THE SAME

(71) Applicant: SAMSUNG ELECTRONICS CO., LTD., Suwon-si (KR)

(72) Inventor: Huishu MA, Suzhou (CN)

(73) Assignee: SAMSUNG ELECTRONICS CO., LTD., Suwon-si (KR)

(21) Appl. No.: 18/646,294

(22) Filed: Apr. 25, 2024

(30) Foreign Application Priority Data
Nov. 22, 2023 (CN) 202311560185.7

(51) Int. Cl. H01L 23/00; H01L 23/31; H01L 25/065

(52) U.S. Cl. CPC H01L 23/562; H01L 23/3128; H01L 24/48; H01L 25/0657; H01L 24/32; H01L 24/73; H01L 2224/32245; H01L 2224/48225; H01L 2224/73215; H01L 2225/0651; H01L 2225/06562

(57) ABSTRACT

Provided is a semiconductor package structure including a substrate, a plurality of chips on the substrate in a second direction perpendicular to a surface of the substrate, a plurality of bonding wires connecting the plurality of chips to bonding pads included in the substrate, respectively, and a molding layer on the substrate, the molding layer encapsulating the plurality of chips and the plurality of bonding wires, wherein at least one first chip of the plurality of chips includes an overhanging portion protruding with respect to a second chip of the plurality of chips on the at least one first chip in a first direction parallel to the surface of the substrate, and wherein a support is on the at least one first chip.

### CROSS-REFERENCE TO RELATED APPLICATION

This application claims priority to Chinese Patent Application No. 202311560185.7, filed on Nov. 22, 2023, in the China National Intellectual Property Administration, the disclosure of which is incorporated by reference herein in its entirety.

### BACKGROUND

### 1. Field

Embodiments of the present disclosure relate to a semiconductor package structure and a method of manufacturing the semiconductor package structure.

### 2. Description of Related Art

Along with the development of the electronic industry, electronic components mounted on electronic devices have become increasingly miniaturized and light weighted. For example, semiconductor package structures that are mounted on electronic components and handle high-capacity data while having relatively small volumes are being developed. Thus, a three-dimensional semiconductor package structure including a plurality of chips stacked to one another has been proposed.

In the existing semiconductor package structures, chips with identical or different specifications, types, and sizes may be stacked. When at least one portion of an upper chip protrudes with respect to a lower chip (e.g., a size of the lower chip is less than a size of the upper chip), the at least one portion of the upper chip may be in an overhanging state, that is, the upper chip includes an overhanging portion. Because chips may be generally thin, they may experience defects such as jitter, chip fragmentation, and non-bonding when performing a wire bonding operation (wire bonding process). Further, when stress is applied to the overhanging portion of the upper chip, the overhanging portion is prone to bending. Therefore, during the manufacturing of semiconductor package structures, there is a high likelihood that package yields will be reduced due to the overhanging portion of the upper chip.

### SUMMARY

One or more embodiments are directed to improving the overhanging defect caused by an overhanging portion of an upper chip during a wire bonding process.

One or more embodiments provide a semiconductor package structure and a method of manufacturing the semiconductor package structure that improves or reduces the overhanging defect caused by the overhanging portion of the upper chip by increasing the mechanical strength of the upper chip.

According to an aspect of an embodiment, there is provided a semiconductor package structure including a substrate, a plurality of chips stacked on the substrate in a second direction perpendicular to a surface of the substrate, a plurality of bonding wires connecting the plurality of chips to bonding pads included in the substrate, respectively, and a molding layer on the substrate, the molding layer encapsulating the plurality of chips and the plurality of bonding wires, wherein at least one first chip of the plurality of chips includes an overhanging portion protruding with respect to a second chip of the plurality of chips on the at least one first chip in a first direction parallel to the surface of the substrate, and wherein a support is on the at least one first chip.

A thickness of the support in the second direction may be equal to or less than a height of a wire loop of a corresponding bonding wire of the plurality of bonding wires.

The support may include a rigid material.

The rigid material may include silicon, a metal or a polymer resin.

Both end portions of the at least one first chip in the first direction may protrude with respect to the second chip on the at least one first chip.

One end portion of the at least one first chip in the first direction may protrude with respect to the second chip on the at least one first chip, and the other end portion of the at least one first chip in the first direction may be aligned with the second chip on the at least one first chip.

One end portion of the at least one first chip in the first direction may protrude with respect to one end portion of the second chip on the at least one first chip in the first direction, and the other end portion of the second chip on the at least one first chip in the first direction may protrude with respect to the other end portion of the at least one first chip in the first direction.

According to another aspect of an embodiment, there is provided a method of manufacturing a semiconductor package structure including providing a substrate, providing a first chip on the substrate along a second direction perpendicular to a surface of the substrate, providing a second chip on the first chip, the second chip including an overhanging portion protruding with respect to the first chip in a first direction parallel to the surface of the substrate, providing a support on the second chip and exposing a bonding pad included in the second chip, providing a bonding wire to connect the bonding pad included in the second chip to a bonding pad included in the substrate, and providing a molding layer on the substrate and encapsulating the first chip, the second chip, and the bonding wire.

A thickness of the support in the second direction may be equal to or less than a height of a wire loop of the bonding wire.

The support may include a rigid material.

The rigid material may include silicon, a metal or a polymer resin.

The second chip may include another overhanging portion protruding with respect to the first chip in the first direction.

According to another aspect of an embodiment, there is provided a semiconductor package structure including a substrate, a first chip on the substrate, a second chip on the first chip, a third chip on the second chip, a plurality of bonding wires connecting the first chip, the second chip, and the third chip to bonding pads included in the substrate, respectively, a first support between the first chip and the second chip, and a molding layer on the substrate, wherein the second chip includes an overhanging portion protruding with respect to first chip in a first direction parallel to a surface of the substrate.

A thickness of the first support in a second direction perpendicular to the surface of the substrate may be equal to or less than a height of a wire loop of a bonding wire of the plurality of bonding wires connecting the second chip to a bonding pad included in the substrate.

The first support may include a rigid material.

The rigid material may include silicon, a metal or a polymer resin.

Both end portions of the second chip in the first direction may protrude with respect to the first chip in the first direction.

At least one of end portions of the third chip in the first direction may protrude with respect to at least one of end portions of the second chip in the first direction.

The semiconductor package structure may further include a second support on the third chip opposite to the second chip.

A thickness of the second support in the second direction may be equal to or less than a height of a wire loop of a bonding wire of the plurality of bonding wires connecting the third chip to a bonding pad included in the substrate.

### BRIEF DESCRIPTION OF DRAWINGS

The above and/or other aspects will become clear and more easily understood from the following description for embodiments taken in conjunction with the accompanying drawings, in which:

FIG. 1 is a schematic cross-sectional view illustrating a semiconductor package structure according to an embodiment;

FIG. 2 is a schematic cross-sectional view illustrating a semiconductor package structure according to another embodiment;

FIG. 3 is a schematic cross-sectional view illustrating a semiconductor package structure according to yet another embodiment; and

FIGS. 4A, 4B, 4C, 4D, 4E, 4F, 4G, 4H, 4I, and 4J are cross-sectional views illustrating a method of manufacturing a semiconductor package structure according to an embodiment.

### DETAILED DESCRIPTION

Embodiments of the present disclosure will be more fully described with reference to the accompanying drawings in which exemplary embodiments of the present disclosure are illustrated. However, the present disclosure may be implemented in many different forms, and should not be constructed as being limited to the embodiments set forth herein. Rather, these embodiments are provided so that the present disclosure will be thorough and complete, and will fully convey the concepts of the embodiments of the present disclosure to those of ordinary skill in the art.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms (including technical and scientific terms) used herein have the same meaning as commonly understood by those of ordinary skill in the art of which the present disclosure is as a part. Terms, such as those defined in commonly used dictionaries, should be interpreted as having meanings that are consistent with their meaning in the context of the relevant art, and will not be interpreted in an idealized or overly formal sense unless expressly so defined herein.

In the following description, for the purposes of explanation, numerous specific details are set forth to provide a thorough understanding of various exemplary embodiments. It is apparent, however, that various exemplary embodiments may be practiced without these specific details or with one or more equivalent arrangements.

Embodiments of the present disclosure will be described in detail hereinafter with reference to the accompanying drawings. Throughout the specification, the like components are referred to by the like reference numerals, and the repeated descriptions thereof may be omitted for conciseness of the description.

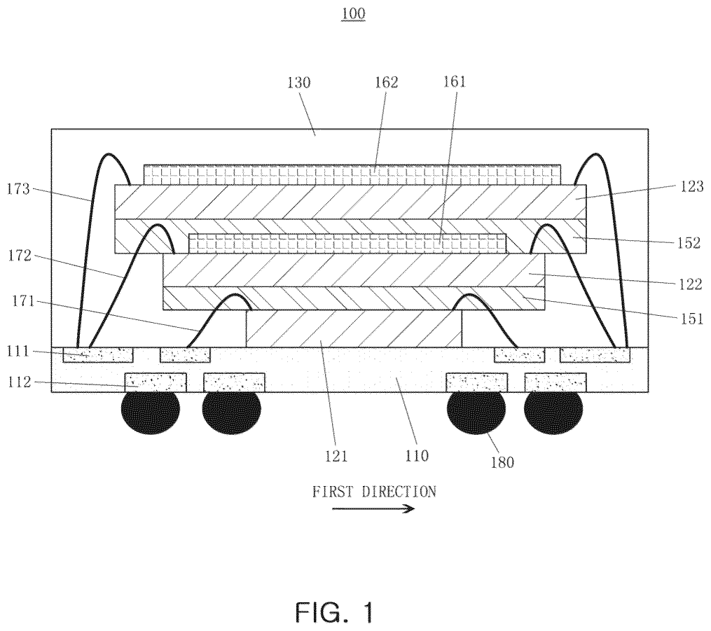

FIG. 1 is a schematic cross-sectional view illustrating a semiconductor package structure according to an embodiment.

Referring to FIG. 1, a semiconductor package structure 100 according to an embodiment may include a substrate 110, a plurality of chips sequentially stacked on the substrate 110, and a molding layer 130 disposed on the substrate 110 and encapsulating the plurality of chips.

The substrate 110 may be a printed circuit board (PCB). For example, the substrate 110 may be a multilayer printed circuit board. However, embodiments are not necessarily limited thereto. The substrate 110 has an upper surface and a lower surface opposite to the upper surface. The substrate 110 may include an upper bonding pad 111 disposed on the upper surface, a lower bonding pad 112 disposed on the lower surface, and an internal wire disposed inside the substrate 110 to electrically connect the upper bonding pad 111 and the lower bonding pad 112.

In an embodiment, the package substrate 110 may include a substrate base. The substrate base may include a single base layer or a structure in which a plurality of base layers are stacked. In an embodiment, the substrate base may include at least one material selected from a phenolic resin, an epoxy resin, and polyimide. The substrate base may include, for example, at least one material selected from flame retardant 4 (FR4), a tetrafunctional epoxy resin, polyphenyl ether, an epoxy resin/a polyphenylene oxide, bismaleimide triazine (BT), polyamide, cyanoacrylate ester, polyimide, and a liquid crystal polymer. However, embodiments are not necessarily limited thereto.

The chips may be mounted on the substrate 110 by front mounting or flip mounting, and may include a first chip 121, a second chip 122 and a third chip 123 sequentially stacked on the upper surface of the substrate 110. Types and structures of the first chip 121, the second chip 122 and the third chip 123 may be the same. However, in some embodiments, the types and structures of the first chip 121, the second chip 122 and the third chip 123 may be partially or completely different.

In an embodiment, the chip may correspond to a memory chip, a logic chip, an analog chip, or a combination thereof. The memory chip may include dynamic random access memory (DRAM) circuits, static random access memory (SRAM) circuits, flash memory access memory circuits, magnetic random access memory (MRAM) circuits, resistive random access memory (ReRAM) circuits, ferroelectric random access memory (FeRAM) circuits, or phase change random access memory (PcRAM) circuits integrated on and/or in a semiconductor substrate. The logic chip or the analog chip may include logic circuits or analog circuits integrated on and/or in the semiconductor substrate, respectively.

The first chip 121 may be disposed on the upper surface of the substrate 110, and electrically connected to the substrate 110. The first chip 121 may be mounted on the substrate 110 by means of wire bonding. For example, a surface of the first chip 121 facing the substrate 110 may be attached to the upper surface of the substrate 110 through an adhesive layer), and a bonding pad disposed on a surface of the first chip 121 opposite to the substrate 110 may be electrically connected to an upper bonding pad 111 disposed on the upper surface of the substrate 110 through a first bonding wire 171. However, the mounting form of the first chip 121 on the substrate 110 is not limited thereto.

The second chip 122 may be disposed on the first chip 121, and may be attached to the first chip 121 through a first adhesive layer 151. A bonding pad disposed on a surface of the second chip 122 opposite to the first chip 121 may be electrically connected to the upper bonding pad 111 disposed on the upper surface of the substrate 110 through a second bonding wire 172. In a first direction (horizontal direction) substantially parallel to the upper surface of the substrate 110, both end portions of the second chip 122 may protrude outwardly with respect to the first chip 121. For example, in the first direction, a left end portion of the second chip 122 may protrude outwardly with respect to a left end portion of the first chip 121, and a right end portion of the second chip 122 may protrude outwardly with respect to a right end portion of the first chip 121. In this case, in the first direction, a length of the second chip 122 is greater than a length of the first chip 121. A portion of the second chip 122 that protrudes with respect to the first chip 121 in the first direction may be referred to as an overhanging portion. For example, with respect to the first chip 121, the second chip 122 may include two overhanging portions in the first direction. In an embodiment, the two overhanging portions of the second chip 122 may have the same length in the first direction. However, embodiments are not limited thereto, for example, the two overhanging portions of the second chip 122 may have different lengths in the first direction.

A third chip 123 may be disposed on the second chip 122, and may be attached to the second chip 122 through a second adhesive layer 152. A bonding pad disposed on a surface of the third chip 123 opposite to the second chip 122 may be electrically connected to the upper bonding pad 111 disposed on the upper surface of the substrate 110 through a third bonding wire 173. In the first direction, both end portions of the third chip 123 may protrude outwardly with respect to the second chip 122. For example, in the first direction, a left end portion of the third chip 123 may protrude outwardly with respect to a left end portion of the second chip 122, and a right end portion of the third chip 123 may protrude outwardly with respect to a right end portion of the second chip 122. In this case, in the first direction, a length of the third chip 123 is greater than a length of the second chip 122. A portion of the third chip 123 that protrudes with respect to the second chip 122 in the first direction may be referred to as an overhanging portion. For example, with respect to the second chip 122, the third chip 123 may include two overhanging portions in the first direction. In an embodiment, the two overhanging portions of the third chip 123 may have the same length in the first direction. However, embodiments are not limited thereto, for example, the two overhanging portions of the third chip 123 may have different lengths in the first direction.

In an embodiment, the bonding wires 171, 172 and 173 may be formed through a wire bonding process. However, during the wire bonding process of forming the bonding wires 172 and 173, forces will be applied to the overhanging portions of the second chip 122 and the third chip 123. Since chips are usually thin, the second chip 122 and the third chip 123 are susceptible to overhanging defects such as jitter, chip fragmentation, and non-bonding due to the overhanging portions when performing the wire bonding process.

In an embodiment, wire loops of the bonding wires 171, 172 and 173 may be encapsulated by the adhesive layers 151 and 152 and the molding layer 130. For example, the wire loop of the first bonding wire 171 may be encapsulated by the first adhesive layer 151, the wire loop of the second bonding wire 172 may be encapsulated by the second adhesive layer 152, and the wire loop of the third bonding wire 173 may be encapsulated by the molding layer 130.

In an embodiment, a first support 161 and a second support 162 may be respectively disposed on the second chip 122 and the third chip 123 to increase the mechanical strength of the second chip 122 and the third chip 123, thereby improving the overhanging problem due to the overhanging portion of the upper chip.

The first support 161 may be disposed on the second chip 122, and may be encapsulated by the second adhesive layer 152. As illustrated in FIG. 1, an upper surface and a side surface of the first support 161 may be coved by the second adhesive layer 152, and a lower surface of the first support 161 may be attached to an upper surface of the second chip 122. In an embodiment, the first support 161 may be bonded to the second chip 122 and the third chip 123 via the second adhesive layer 152 covering thereon. However, embodiments are not limited thereto. For example, the lower surface of the first support 161 may be attached to the second chip 122 through an additional adhesive layer.

As illustrated in FIG. 1, in a vertical direction perpendicular to the first direction (e.g., a thickness direction of the substrate 110), a thickness of the first support 161 may be equal to or less than a height of the wire loop of the second bonding wire 172, and the height of the wire loop of the second bonding wire 172 may be less than a thickness of the second adhesive layer 152. Thus, without changing the thickness of the second adhesive layer 152 and without increasing the overall thickness of the semiconductor package structure 100, the overhanging problem due to the overhanging portion of the second chip 122 may be improved by disposing the rigid first support 161.

The second support 162 may be disposed on the third chip 123, and may be encapsulated by the molding layer 130. As illustrated in FIG. 1, an upper surface and a side surface of the second support 162 may be covered by the molding layer 130, and a lower surface of the second support 162 may be attached to an upper surface of the third chip 123. In an embodiment, the second support 162 may be bonded to the third chip 123 via the molding layer 130 covering thereon. However, embodiments are not limited thereto. For example, the lower surface of the second support 162 may be attached to the third chip 123 through an additional adhesive layer.

As illustrated in FIG. 1, in the vertical direction, a thickness of the second support 162 may be equal to or less than a height of the wire loop of the third bonding wire 173, and the height of the wire loop of the third bonding wire 173 may be less than a distance between an upper surface of the molding layer 130 and an upper surface of the third chip 123. Thus, without changing the thickness of the molding layer 130 and without increasing the overall thickness of the semiconductor package structure 100, the overhanging problem due to the overhanging portion of the third chip 123 may be improved by disposing the rigid second support 162.

The first support 161 and the second support 162 may have a certain rigidity, and may be formed using any applicable rigid material. For example, the rigid material may include a conductive material, a semiconductor material or an insulating material. For example, the rigid material may include silicon, a metal (such as copper and its alloy), a polymer resin (such as an epoxy resin, a rigid thin film, etc.), and the like. When the rigid material is silicon, the chip disposed below is the first support 161 and the second support 162 may be a non-functional chip. For example, when the first support 161 includes silicon, the second chip 122 is a non-functional chip.

For the subsequent wire bonding process, the bonding pads of the second chip 122 and the third chip 123 need to be exposed and not covered by the first support 161 and the second support 162. Thus, sizes of the first support 161 and the second support 162 may be less than sizes of the second chip 122 and the third chip 123 below the first support 161 and the second support 162, respectively. In addition, the support should be as large as possible to enhance support in the case of ensuring that the bonding wires are avoided. In an embodiment, for example, on a plane parallel to the upper surface of the substrate 110, areas of the first support 161 and the second support 162 may be less than areas of the second chip 122 and the third chip 123 below them.

For example, a size of the first support 161 may be disposed to be less than a size of the second chip 122 to expose the bonding pad of the second chip 122. For example, on the plane parallel to the upper surface of the substrate 110, an area of the first support 161 may be less than an area of the second chip 122. For example, as illustrated in FIG. 1, in the first direction, a length of the first support 161 may be less than a length of the second chip 122 and greater than a length of the first chip 121. In this case, in the first direction, the first support 161 may be disposed so that a left end portion of the first support 161 is located on a left overhanging portion of the second chip 122 and a right end portion of the first support 161 is located on a right overhanging portion of the second chip 122. However, embodiments are not limited thereto. In another embodiment, the first support 161 may be disposed so that the left end portion of the first support 161 and the right end portion of the first support 161 is located on the first chip 121 such that a length of the first support member 161 may be less than a length of the first chip 121 in the first direction.

Similarly, a size of the second support 162 may be disposed to be less than a size of the third chip 123 to expose the bonding pad of the third chip 123. For example, on the plane parallel to the upper surface of the substrate 110, an area of the second support 162 may be less than an area of the third chip 123. For example, as illustrated in FIG. 1, in the first direction, a length of the second support 162 may be less than a length of the third chip 123 and greater than a length of the second chip 122. In this case, in the first direction, the second support 162 may be disposed so that a left end portion of the second support 162 is located on a left overhanging portion of the third chip 123 and a right end portion of the second support 162 is located on a right overhanging portion of the third chip 123. However, embodiments are not limited thereto. In another embodiment, the second support 162 may be disposed so that the left end portion of the second support 162 and the right end portion of the second support 162 is located on the second chip 122 such that a length of the second support 162 may be less than a length of the second chip 122 in the first direction. According to another embodiment, the second support 162 may be disposed so that the left end portion of the second support 162 and the right end portion of the second support 162 is located on the first chip 121 such that a length of the second support 162 may be less than a length of the first chip 121 in the first direction.

The molding layer 130 may be disposed on the substrate 110, and may encapsulate the first chip 121, the second chip 122, the third chip 123, the first adhesive layer 151, the second adhesive layer 152, the second support 162 and the bonding wire 170 on the substrate 110 to protect internal components (e.g., chips) of the semiconductor package structure 100. In an embodiment, the molding layer 130 may include an epoxy molding compound (EMC), an Ajinomoto buildup film (ABF), FR-4, bismaleimide triazine (BT), and the like. However, embodiments are not necessarily limited thereto.

In an embodiment, the semiconductor package structure 100 may further include an external connection terminal 180 disposed on the bonding pad 112 of the substrate 110. In an embodiment, the external connection terminal 180 may be, for example, a solder ball or a solder block. The external connection terminal 180 may include a solder material. In an embodiment, the solder material may include, for example, tin (Sn), indium (In), bismuth (Bi), antimony (Sb), copper (Cu), silver (Ag), zinc (Zn), lead (Pb) and/or an alloy thereof. The external connection terminal 180 may be electrically connected to an external device.

In an embodiment, by disposing a rigid support on an upper chip, a mechanical strength of the upper chip may be increased, thereby improving the overhanging defect due to the overhanging portion and further increasing a length of the overhanging portion of the upper chip. The rigid support disposed on the upper chip may be encapsulated by the corresponding adhesive layer or molding layer, and may be disposed so that a thickness thereof in a vertical direction is less than a height of the wire loop of the corresponding bonding wire, and thus, the semiconductor package structure may not only not change the thickness of the corresponding adhesive layer or molding layer, but may also not increase the overall thickness of the semiconductor package structure.

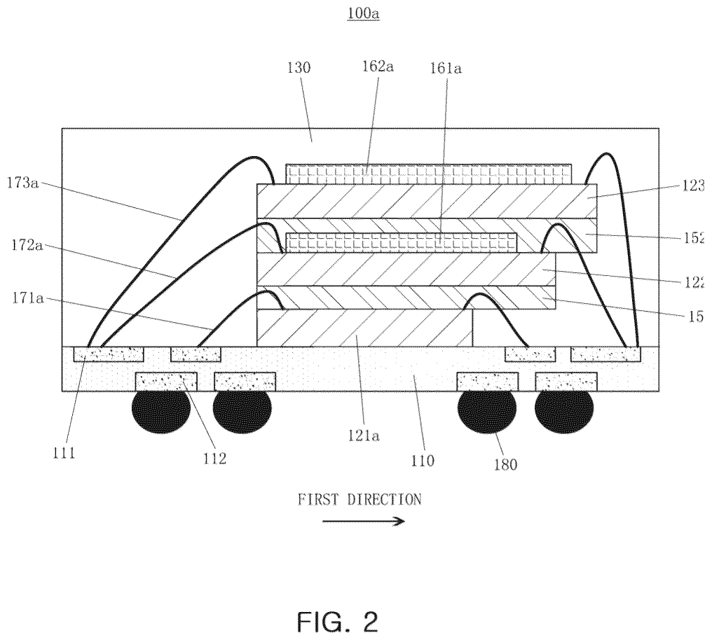

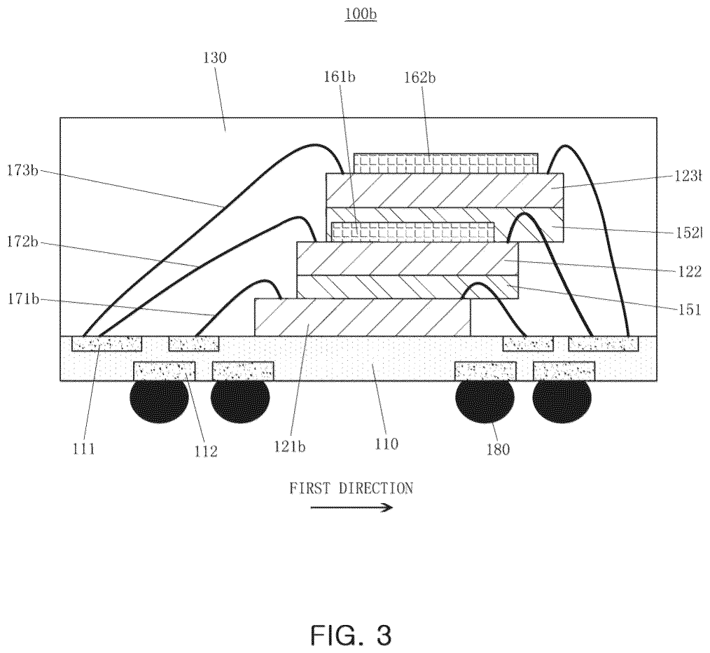

FIG. 2 is a schematic cross-sectional view illustrating a semiconductor package structure according to another embodiment. FIG. 3 is a schematic cross-sectional view illustrating a semiconductor package structure according to yet another embodiment. In FIGS. 2 and 3, differences from the semiconductor package structure illustrated in FIG. 1 will be described mainly, to avoid unnecessary repeated description.

Referring to FIGS. 2 and 3, semiconductor package structures 100a and 100b according to embodiments may each include a substrate 110, a plurality of chips sequentially stacked on the substrate 110, and a molding layer 130 disposed on the substrate 110 and encapsulating the plurality of chips.

In an embodiment, the chips include first chips 121a and 121b, second chips 122a and 122b and third chips 123a and 123b sequentially stacked on the upper surface of the substrate 110.

The first chips 121a and 121b may be disposed on the upper surface of the substrate 110, and may be electrically connected to the substrate 110 through first bonding wires 171a and 171b, respectively.

The second chips 122a and 122b may be disposed on the first chips 121a and 121b, respectively and may be electrically connected to the substrate 110 through second bonding wires 172a and 172b, respectively. The second chips 122a and 122b may be attached to the first chips 121a and 121b through first adhesive layers 151a and 151b, respectively.

The third chips 123a and 123b may be disposed on the second chips 122a and 122b, respectively and may be electrically connected to the substrate 110 through third bonding wires 173a and 173b, respectively. The third chips 123a and 123b may be attached to the second chips 122a and 121b through second adhesive layers 152a and 152b, respectively.

In the semiconductor package structure 100a according to the embodiment illustrated in FIG. 2, in the first direction, one end portion of the second chip 122a may protrude outwardly with respect to the first chip 121a, and the other end portion of the second chip 122a may be aligned with the first chip 121a. For example, a right end portion of the second chip 122a may protrude outwardly with respect to a right end portion of the first chip 121a, and a left end portion of the second chip 122a may be aligned with a left end portion of the first chip 121a. In the first direction, an end portion of the third chip 123a may protrude outwardly with respect to the second chip 122a, and the other end portion of the third chip 123a may be aligned with the second chip 122a. For example, a right end portion of the third chip 123a may protrude outwardly with respect to a right end portion of the second chip 122a, and a left end portion of the third chip 123a may be aligned with a left end portion of the second chip 122a. However, embodiments are not limited thereto.

In the semiconductor package structure 100b according to the embodiment illustrated in FIG. 3, in the first direction, one end portion of the second chip 122b may protrude outwardly with respect to the first chip 121b, and the other end portion of the second chip 122b may be on the first chip 121b. For example, a right end portion of the second chip 122b may protrude outwardly with respect to a right end portion of the first chip 121b, and a left end portion of the first chip 121b may protrude outwardly with respect to a left end portion of the second chip 122b (i.e., the left end portion of the second chip 122b may be on the first chip 121b). For example, in the first direction, the right end portion of the second chip 122b may protrude beyond the right end portion of the first chip 121b, and the left end portion of the first chip 121b may protrude beyond the left end portion of the second chip 122b. In the first direction, one end portion of the third chip 123b may protrude outwardly with respect to the second chip 122b, and the other end portion of the third chip 123b may be on the second chip 122b. For example, a right end portion of the third chip 13b may protrude outwardly with respect to a right end portion of the second chip 122b, and a left end portion of the second chip 122b may protrude outwardly with respect to a left end portion of the third chip 123b (i.e., the left end portion of the third chip 123b may be on the second chip 122b). For example, in the first direction, the right end portion of the third chip 123b may protrude beyond the right end portion of the second chip 122b, and the left end portion of the second chip 122b may protrude beyond the left end portion of the third chip 123b.

During the wire bonding process of the second bonding wires 172a and 172b and the third bonding wires 173a and 173b, overhanging defects such as jitter, chip fragmentation, non-bonding and the like may occur due to the overhanging portions of the upper chips 122a and 122b as well as 123a and 123b.

In an embodiment, first supports 161a and 161b and second supports 162a and 162b may be respectively disposed on the second chips 122a and 122b and the third chips 123a and 123b to increase the mechanical strength of the second chips 122a and 122b and the third chips 123a and 123b, thereby improving the overhanging defects due to the overhanging portions of the upper chips 122a and 122b as well as 123a and 123b.

The first supports 161a and 161b may be disposed on the second chips 122a and 122b, and may be encapsulated by the second adhesive layers 152a and 152b. The wire loops of the second bonding wires 172a and 172b may be encapsulated by the second adhesive layers 152a and 152b. In an embodiment, in a thickness direction, thicknesses of the first supports 161a and 161b may be equal to or less than heights of the wire loops of the second bonding wires 172a and 172b, and the heights of the wire loops of the second bonding wires 172a and 172b may be less than thicknesses of the second adhesive layers 152a and 152b.

Similarly, the second supports 162a and 162b may be disposed on the third chips 123a and 123b, and may be encapsulated by the molding layer 130. The wire loops of the third bonding wires 173a and 173b may be encapsulated by the molding layer 130. In an embodiment, in the thickness direction, thicknesses of the second supports 162a and 162b may be equal to or less than heights of the wire loops of the third bonding wires 173a and 173b, and heights of the wire loops of the third bonding wires 173a and 173b may be less than a distance between an upper surface of the molding layer 130 and upper surfaces of the third chips 123a and 123b.

Thus, without changing the thicknesses of the second adhesive layers 152a and 152b and the molding layer 130 and without increasing the overall thickness of the semiconductor package structures 100a and 100b, the mechanical strength of the second chips 122a and 122b and the third chips 123a and 123b may be increased by disposing the rigid first supports 161a and 161b and second supports 162a and 162b, thereby the overhanging defects due to the overhanging portions of the second chips 122a and 122b and the third chips 123a and 123b may be improved.

However, embodiments are not limited thereto. The arrangement of the first chip, the second chip and the third chip may be modified and combined in various ways. For example, the left end portion of the second chip may be aligned with the left end portion of the first chip, and the right end portion of the second chip may protrude with respect to the right end portion of the first chip in the first direction. The right end portion of the third chip may protrude with respect to the right end portion of the second chip, and the left end portion of the second chip may protrude with respect to the left end portion of the third chip in the first direction.

Furthermore, according to an embodiment, the stacked number of chips may not be limited to three, and may vary. For example, the stacked number of the chips may be two or four or more.

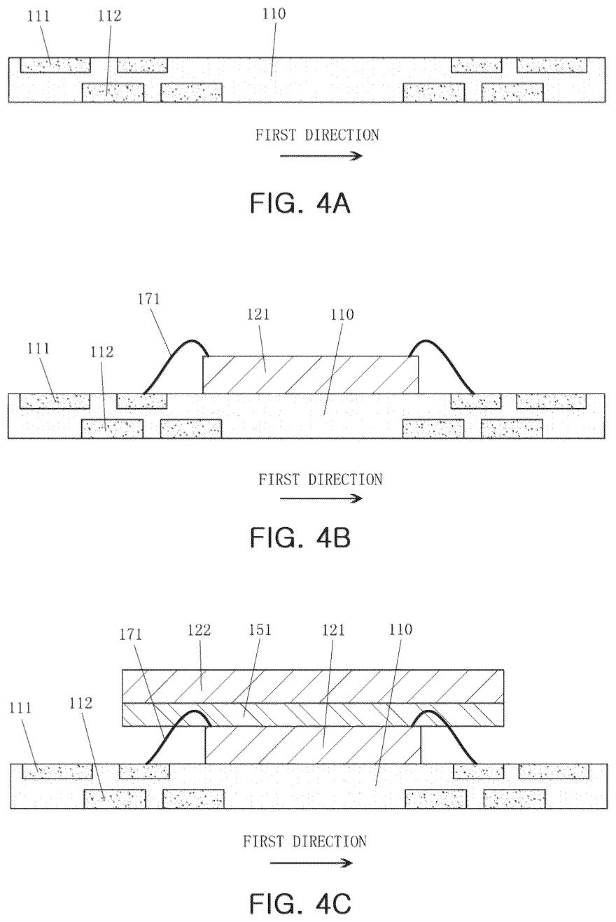

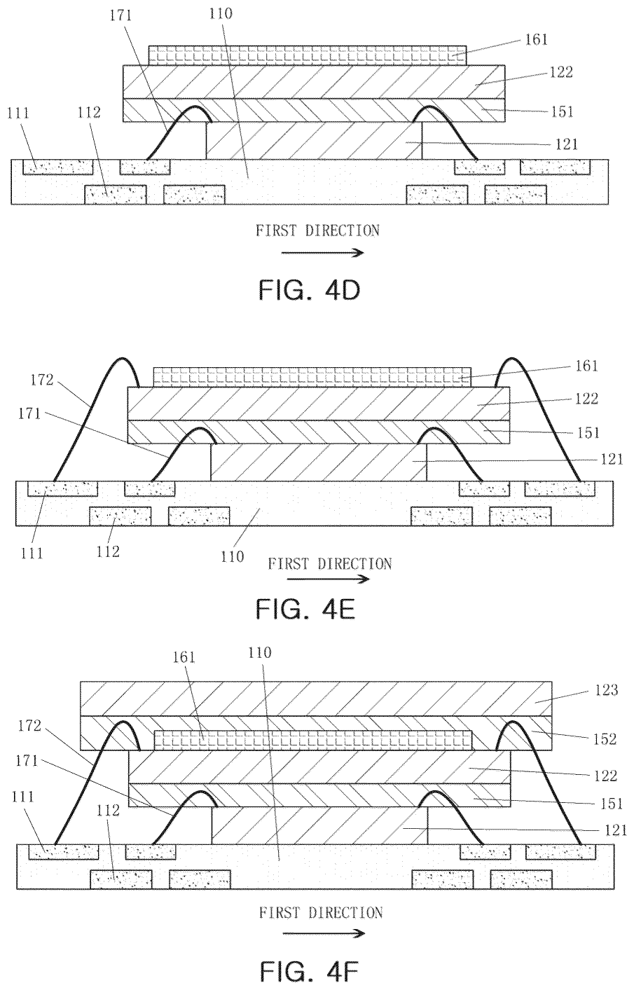

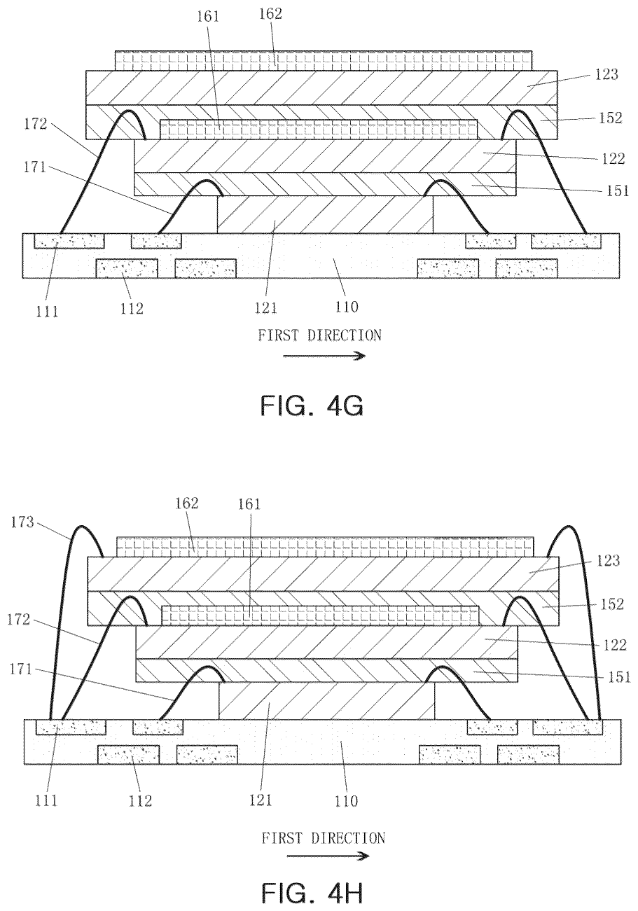

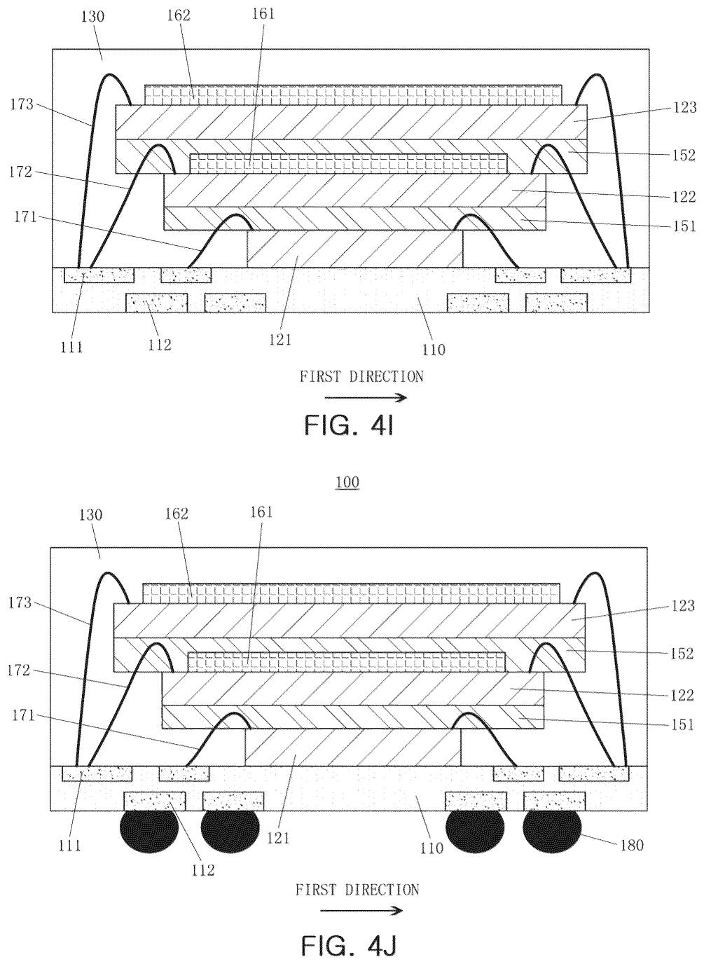

FIGS. 4A to 4J are cross-sectional views illustrating a method of manufacturing a semiconductor package structure according to an embodiment. The manufacturing method illustrated in FIGS. 4A to 4J corresponds to the semiconductor package structure 100 of FIG. 1.

Referring to FIGS. 1 and 4A, a substrate 110 may be provided. The substrate 110 may have an upper surface and a lower surface opposite to the upper surface. The substrate 110 may include an upper bonding pad 111 disposed on the upper surface, a lower bonding pad 112 disposed on the lower surface, and an internal wire disposed inside the substrate 110 to electrically connect the upper bonding pad 111 and the lower bonding pad 112.

Referring to FIG. 4B, a first chip 121 may be disposed on the upper surface of the substrate 110. The first chip 121 may not cover the upper bonding pad 111 and may expose the upper bonding pad 111. Then, a wire bonding process may be performed on the first chip 121 to form a first bonding wire 171. The first bonding wire 171 may electrically connect the bonding pad on the first chip 121 and the upper bonding pad 111 of the substrate 110. The wire bonding process may be performed using, for example, a threaded capillary, but it is not limited thereto.

Referring to FIG. 4C, an adhesive material may be applied to the first chip 121, and the adhesive material may be disposed to encapsulate the wire loop of the first bonding wire 171. Then, the adhesive material may be cured to form the first adhesive layer 151. Subsequently, the second chip 122 may be attached to the first adhesive layer 151. In the first direction, both end portions of the second chip 122 may protrude outwardly with respect to the first chip 121. In this case, the length of the second chip 122 in the first direction may be greater than the length of the first chip 121 in the first direction, and the second chip 122 may include two overhanging portions protruding with respect to the first chip 121 in the first direction.

Referring to FIG. 4D, the rigid material may be attached to the second chip 122 to form the first support 161. The first support 161 may be formed using any applicable rigid material. For example, the rigid material may include silicon, a metal (such as copper and its alloy), a polymer resin (such as an epoxy resin, a rigid thin film, etc.), and the like. The first support 161 may increase the mechanical strength of the second chip 122 to improve the overhanging defect caused by the overhang portion, and may further increase the length of the overhang portion of the second chip 122. Thus, the size of the first support 161 may be selected as long as it does not cover the bonding pad of the second chip 122.

Referring to FIG. 4E, a wire bonding process may be performed on the second chip 122 to form a second bonding wire 172. The second bonding wire 172 may electrically connect the bonding pad (not illustrated) of the second chip 122 and the upper bonding pad 111 of the substrate 110. Here, in order not to change the thickness of the first adhesive layer 151 and not to increase the overall thickness of the semiconductor package structure 100, the thickness of the first support 161 may be equal to or less than the height of the wire loop of the second bonding wire 172.

Referring to FIG. 4F, an adhesive material may be applied to the second chip 122, and the adhesive material may be disposed to encapsulate the wire loop of the second bonding wire 172. Then, the adhesive material may be cured to form the second adhesive layer 152. Subsequently, the third chip 123 may be attached to the second adhesive layer 152. In the first direction, both end portions of the third chip 123 may protrude outwardly with respect to the second chip 122. In this case, the length of the third chip 123 in the first direction may be greater than the length of the second chip 122 in the first direction, and the third chip 123 may include two overhanging portions protruding with respect to the second chip 122 in the first direction.

Referring to FIG. 4G, the rigid material may be attached to the third chip 123 to form the second support 162. The second support 162 may be formed using any applicable rigid material. For example, the rigid material may include silicon, a metal (such as copper and its alloy), a polymer resin (such as an epoxy resin, a rigid thin film, etc.), and the like. The second support 162 may increase the mechanical strength of the third chip 123 to improve the overhanging defect caused by the overhang portion, and may further increase the length of the overhanging portion of the third chip 123. Thus, the size of the second support 162 may be suitably selected as long as it does not cover the bonding pad of the third chip 123, without any particular limitation.

Referring to FIG. 4H, a wire bonding process may be performed on the third chip 123 to form a third bonding wire 173. The third bonding wire 173 may electrically connect the bonding pad of the third chip 123 and the upper bonding pad 111 of the substrate 110. Here, in order maintain the thickness of the molding layer 130 and the overall thickness of the semiconductor package structure 100 from changing or increasing, the thickness of the second support 162 may be equal to or less than the height of the wire loop of the third bonding wire 173.

Referring to FIG. 4I, a molding layer 130 encapsulating a first chip 121, a second chip 122, a third chip 123, a first adhesive layer 151, a second adhesive layer 152, a second support 162, a first bonding wire 171, a second bonding wire 172 and a third bonding wire 173 may be formed on the substrate 110. Processes known in the art may be used to form the molding layer 130, without any particular limitation.

Referring to FIG. 4J, an external connection terminal 180 attached to the lower bonding pad 112 may be formed on the lower surface of the substrate 110. In an embodiment, the external connection terminal 180 may be, for example, a solder ball or a solder block.

Accordingly, the semiconductor package structure 100 according to an embodiment may be manufactured.

However, methods of manufacturing the semiconductor package structure according to embodiments are not limited thereto, and various modifications may be made.

It should be understood that embodiments described herein should be considered in a descriptive sense only and not for purposes of limitation. Descriptions of features or aspects within each embodiment should typically be considered as available for other similar features or aspects in other embodiments.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package structure comprising:
a substrate;
a plurality of chips stacked on the substrate in a second direction perpendicular to a surface of the substrate;
a plurality of bonding wires connecting the plurality of chips to bonding pads included in the substrate, respectively; and
a molding layer on the substrate, the molding layer encapsulating the plurality of chips and the plurality of bonding wires,
wherein at least one first chip of the plurality of chips comprises an overhanging portion protruding with respect to a second chip of the plurality of chips on the at least one first chip in a first direction parallel to the surface of the substrate, and
wherein a support is on the at least one first chip.

2. The semiconductor package structure as claimed in claim 1, wherein a thickness of the support in the second direction is equal to or less than a height of a wire loop of a corresponding bonding wire of the plurality of bonding wires.

3. The semiconductor package structure as claimed in claim 1, wherein the support comprises a rigid material.

4. The semiconductor package structure as claimed in claim 3, wherein the rigid material comprises silicon, a metal or a polymer resin.

5. The semiconductor package structure as claimed in claim 1, wherein both end portions of the at least one first chip in the first direction protrude with respect to the second chip on the at least one first chip.

6. The semiconductor package structure as claimed in claim 1, wherein one end portion of the at least one first chip in the first direction protrudes with respect to the second chip on the at least one first chip, and the other end portion of the at least one first chip in the first direction is aligned with the second chip on the at least one first chip.

7. The semiconductor package structure as claimed in claim 1, wherein one end portion of the at least one first chip in the first direction protrudes with respect to one end portion of the second chip on the at least one first chip in the first direction, and the other end portion of the second chip on the at least one first chip in the first direction protrudes with respect to the other end portion of the at least one first chip in the first direction.

8. A method of manufacturing a semiconductor package structure comprising:
providing a substrate;
providing a first chip on the substrate along a second direction perpendicular to a surface of the substrate;
providing a second chip on the first chip, the second chip comprising an overhanging portion protruding with respect to the first chip in a first direction parallel to the surface of the substrate;
providing a support on the second chip and exposing a bonding pad included in the second chip;
providing a bonding wire to connect the bonding pad included in the second chip to a bonding pad included in the substrate; and
providing a molding layer on the substrate and encapsulating the first chip, the second chip, and the bonding wire.

9. The method as claimed in claim 8, wherein a thickness of the support in the second direction is equal to or less than a height of a wire loop of the bonding wire.

10. The method as claimed in claim 8, wherein the support comprises a rigid material.

11. The method as claimed in claim 10, wherein the rigid material comprises silicon, a metal or a polymer resin.

12. The method as claimed in claim 8, wherein the second chip comprises another overhanging portion protruding with respect to the first chip in the first direction.

13. A semiconductor package structure, comprising:
a substrate;
a first chip on the substrate;
a second chip on the first chip;
a third chip on the second chip;
a plurality of bonding wires connecting the first chip, the second chip, and the third chip to bonding pads included in the substrate, respectively;
a first support between the first chip and the second chip; and
a molding layer on the substrate,
wherein the second chip comprises an overhanging portion protruding with respect to first chip in a first direction parallel to a surface of the substrate.

14. The semiconductor package structure as claimed in claim 13, wherein a thickness of the first support in a second direction perpendicular to the surface of the substrate is equal to or less than a height of a wire loop of a bonding wire of the plurality of bonding wires connecting the second chip to a bonding pad included in the substrate.

15. The semiconductor package structure as claimed in claim 13, wherein the first support comprises a rigid material.

16. The semiconductor package structure as claimed in claim 15, wherein the rigid material comprises silicon, a metal or a polymer resin.

17. The semiconductor package structure as claimed in claim 13, wherein both end portions of the second chip in the first direction protrude with respect to the first chip in the first direction.

18. The semiconductor package structure as claimed in claim 13, wherein at least one of end portions of the third chip in the first direction protrudes with respect to at least one of end portions of the second chip in the first direction.

19. The semiconductor package structure as claimed in claim 13, further comprising a second support on the third chip opposite to the second chip.

20. The semiconductor package structure as claimed in claim 19, wherein a thickness of the second support in the second direction is equal to or less than a height of a wire loop of a bonding wire of the plurality of bonding wires connecting the third chip to a bonding pad included in the substrate.
